(19) United States
(12) Patent Application Publication
(10) Pub. No.: US 2025/0171885 A1
(43) Pub. Date: May 29, 2025

(54) SPRAYED COATING CONTAINING YTTRIUM ALUMINATE, PLASMA-RESISTANT MEMBER COMPRISING SAME, AND MANUFACTURING METHODS THEREOF

(71) Applicant: KoMiCo Ltd., Anseong-si (KR)

(72) Inventors: Ki Won Hong, Anseong-si (KR); Dong Hun Jeong, Anseong-si (KR)

(21) Appl. No.: 18/953,146

(22) Filed: Nov. 20, 2024

(30) Foreign Application Priority Data
Nov. 23, 2023 (KR) 10-2023-0164601
Oct. 29, 2024 (KR) 10-2024-0150029

(51) Int. Cl. C23C 4/134; C23C 4/11

(52) U.S. Cl. CPC C23C 4/134; C23C 4/11

(57) ABSTRACT

Disclosed is a method for plasma spray coating for a sprayed coating containing YAG, which provides a method for manufacturing a plasma sprayed coating, the method comprising: providing a granular powder containing crystalline YAG; forming a plasma stream toward a base material from a plasma spray torch; forming molten droplets of the granular powder by supplying the granular powder to the plasma stream; providing a coolant stream in a direction intersecting the plasma stream containing the molten droplets; and providing the base material with the plasma stream that has undergone the coolant stream, thereby forming a sprayed coating containing a crystalline phase and an amorphous phase.

### CROSS-REFERENCE TO RELATED APPLICATION(S)

This application is based on and claims priority under 35 U.S.C. 119 to Korean Patent Application No. 10-2023-0164601 filed on Nov. 23, 2023 and Korean Patent Application No. 10-2024-0150029 filed on Oct. 29, 2024, in the Korean Intellectual Property Office, the disclosure of which is herein incorporated by reference in its entirety.

### BACKGROUND OF THE INVENTION

### 1. Field of the Invention

The present disclosure relates to an yttrium aluminate-containing sprayed coating and a manufacturing method thereof and, more specifically, to an yttrium aluminate-containing plasma sprayed coating with high crystallinity and manufacturing methods thereof.

### 2. Description of the Prior Art

In recent years, high-integration and ultra-fine line width technologies in semiconductor processes require a plasma etching process under ultra-extreme environments, such as high-density plasma, high cleanliness, and excessive electric shock. In particular, a plasma etching process using a reactant gas containing a halogen element, such as F, Cl, or Br, with strong chemical reactivity involves etching of various deposition materials on the wafer surface, but causes damage to the surface of parts and generation of non-volatile contaminants through chemical and physical reactions with metal or ceramic parts inside a chamber.

Three-dimensional multi-stacking for high integration of 100 layers or more is being applied in the manufacturing of 3D V-NAND flash memory. To this end, a dry etching process has been continuously developed to manufacture a complex three-dimensional structure with a high aspect ratio contact (HARC), wherein etching, cleaning, and deposition processes are repeatedly performed in the chamber.

Examples of the gas type used in the etching process include CF₄, CCl₄, NF₃, HBr, SF₆, Cl₂, and the like, and these process gases are converted into plasma, which etches not only wafers but also components constituting chambers to cause particle generation, resulting in a reduction in productivity, such as a decrease in yield and a shortening in the preventive maintenance (PM) cycle.

To prevent this, various parts inside the chamber are spray coated with various materials, such as Y:O₃, YF₃, YₓO_{y}F_{z}, and YAG, but several issues are caused with this method.

Chemical etching through plasma-charged ions and physical etching through ion bombardment are presented according to the etching mechanism. Therefore, sprayed coatings applied to the inside of the chamber need to ensure resistance to both chemical etching and physical etching. However, Y₂O₃ has the advantage of relatively high hardness and low manufacturing cost, but causes the occurrence of seasoning time at the beginning of the process due to F-ions. YₓO_{y}F_{z} and YF₃ retain excellent resistance to F-ions, but have low resistance to physical etching due to the low hardness of the material itself.

Recently, with the aim of high aspect ratio contact (HARC), HBr gas is used in mixing with Cl₂ and/or O₂ gas to maximize the anisotropic etching effect of Br ions. In etching processes using these process gases, yttrium aluminum garnet (YAG) materials having very high hardness and excellent resistance to hydrogen brittleness are known to be suitable.

However, when a YAG material is used to form a coating by conventional spray coating, the YAG material forms a coating in an amorphous state since the material is exposed to an environment of rapid cooling after melting, and thus desired levels of property values are difficult to obtain. Moreover, the crystallization temperature of YAG is 900° C. or higher, which makes it substantially impossible to crystallize a formed sprayed coating member through heat treatment. Meanwhile, the reduction in plasma output during the spray coating process may slightly increase the degree of crystallization, but result in decreased property values and increased porosity in the formed sprayed coating, and thus this approach cannot also be considered a fundamental solution.

Therefore, there is a need for a coating process capable of minimizing the rapid cooling effect occurring in conventional spray coating and enhancing properties, such as high densification.

### PRIOR ART DOCUMENTS

### Patent Documents

(Patent Document 1) KR 2019-0017333A
(Patent Document 2) KR 2019-0082119A
(Patent Document 3) JP 6918996B
(Patent Document 4) JP 7035293B

### SUMMARY OF THE INVENTION

In order to solve the above-described problems, an aspect of the present disclosure is to provide a spray coating method capable of achieving property enhancement through high densification of an yttrium aluminate-containing sprayed coating.

Another aspect of the present disclosure is to provide a spray coating method capable of achieving property enhancement through high densification of an yttrium aluminate-containing sprayed coating without recrystallization.

Still another aspect of the present disclosure is to provide an yttrium aluminate-containing sprayed coating with a high rate of crystallization and a plasma-resistant member containing the same.

In accordance with an aspect of the present disclosure, there is provided a method for manufacturing a plasma sprayed coating containing YAG, the method including: providing a granular powder containing crystalline YAG; forming a plasma stream toward a base material from a plasma spray torch; forming molten droplets of the granular powder by supplying the granular powder to the plasma stream; providing a coolant stream in a direction intersecting the plasma stream containing the molten droplets; and providing the base material with the plasma stream that has undergone the coolant stream, thereby forming a sprayed coating containing a crystalline phase and an amorphous phase.

The forming of molten droplets may include partially melting the granular powder in a state where the crystalline YAG is contained inside the molten droplets.

The granular powder may have a D50 of 15-75 μm.

The granular powder may have a D50 of 15-45 μm.

The degree of crystallization of the sprayed coating is preferably 45% or more.

The porosity of the sprayed coating is preferably 1-3.1%.

The coolant stream may include water.

The separation distance between the plasma torch and the base material is preferably 80-160 mm.

In the present disclosure, a coolant injector for supplying the coolant stream is preferably included, and the coolant injector is preferably in a ring shape surrounding the plasma stream.

The coolant injector may include a plurality of spray orifices toward the plasma steam, on the inner circumference thereof.

The coolant stream may have a flow rate of 100-500 ml/min. The Vickers hardness of the amorphous phase is preferably 720-800.

The Vickers hardness of the crystalline phase may be 1000-1110.

The ratio of the Vickers hardness of the crystalline phase to the Vickers hardness of the amorphous phase may be 1.3-1.6.

In accordance with another aspect of the present disclosure, there is provided a plasma sprayed coating containing Y—Al—O, wherein Y—Al—O in the sprayed coating includes a crystalline phase and an amorphous phase, the crystalline phase contains YAG, and the Vickers hardness (Hv) of the crystalline phase is 1000 or more.

The ratio of the Vickers hardness of the crystalline phase to the Vickers hardness of the amorphous phase is preferably 1.3 or more.

The degree of crystallization of the YAG, calculated from the XRD pattern of the YAG, is preferably 45% or more.

The cross-section of the sprayed coating preferably includes bright regions showing the crystalline phase on an optical microscopic image, and the average area of the regions is preferably 100 μm or more.

In accordance with still another aspect of the present disclosure, there is provided a plasma-resistant member c-including: a base material; and the above-described sprayed coating formed on the base material.

According to the present disclosure, a spray coating method can be provided capable of achieving property enhancement through high densification of an yttrium aluminate-containing sprayed coating.

Furthermore, according to the present disclosure, a spray coating method can be provided capable of achieving property enhancement through high densification of an yttrium aluminate-containing sprayed coating without recrystallization.

Furthermore, according to the present disclosure, an yttrium aluminate-containing sprayed coating with a high rate of crystallization can be provided.

### BRIEF DESCRIPTION OF THE DRAWINGS

The above and other aspects, features and advantages of the present disclosure will be more apparent from the following detailed description taken in conjunction with the accompanying drawings.

FIG. 1 schematically shows a plasma spray coating apparatus according to an embodiment of the present disclosure.

FIG. 2 is an exemplary plane diagram of the coolant injector in FIG. 1.

FIG. 3 is a SEM image of a granular powder sample manufactured in the present disclosure.

FIGS. 4A to 4F are electron microscopic images taken after the cross-sections of base materials of Examples 1 to 6 were polished, respectively.

FIGS. 5A to 5G are electron microscopic images taken after the cross-sections of base materials of Comparative Example 1 to 7 were polished, respectively.

FIGS. 6A and 6B are optical microscopic images obtained by observing a cross-section and a surface of the coating of Example 1, respectively.

FIGS. 7A and 7B are optical microscopic images obtained by observing a cross-section and a surface of the coating of Comparative Example 3, respectively.

FIGS. 8A and 8B are optical microscopic images obtained by observing the surfaces of coatings of Comparative Examples 1 and 2, respectively.

FIGS. 9A to 9D show XRD analysis results of plasma sprayed coatings formed in Comparative Examples 1 and 2 and Examples 1 and 2, respectively.

FIG. 10 is a graph showing the results of indexing XRD peaks for some patterns in FIG. 9.

### DETAILED DESCRIPTION OF THE EXEMPLARY EMBODIMENTS

Unless defined otherwise, all technical and scientific terms used herein have the same meaning as commonly understood by a person skilled in the art to which this disclosure pertains. In general, the nomenclature used herein are well known and commonly employed in the art.

Throughout the specification, when a component “includes” or “comprises” an element, unless there is a description contrary thereto, the component can further include other elements, not excluding the other elements.

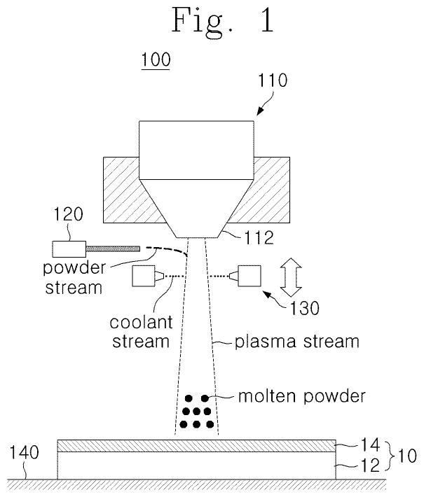

FIG. 1 schematically shows a plasma spray coating apparatus according to an embodiment of the present disclosure. Hereinafter, a manufacturing method of the present disclosure will be described with reference to the drawing.

Referring to FIG. 1, a plasma spray apparatus 100 includes a plasma torch 110 or a plasma gun, a powder injector 120, and a coolant injector 130. The apparatus may also include a stage 140 configured to load a base material 12 on which a coating is to be formed.

In the present disclosure, the base material may be any material. For example, a material, such as aluminum, stainless steel, yttria, alumina, or quartz, may be used.

In the present disclosure, the separation distance between the plasma torch and the base material may be appropriately set. In the present disclosure, the separation distance means the distance from a nozzle 112 of the plasma torch to the surface of the base material 12, and the separation distance is preferably maintained in the range of 80-160 mm to provide molten powder droplets without loss, thereby improving yield. If the separation distance is less than 80 mm, the temperature of droplets is too high, causing a reduction in the rate of crystallization, and if the separation distance is more than 160 mm, the properties of the coating thus obtained are rapidly degraded.

The plasma torch 110 is configured to generate an arc discharge between a negative electrode and a positive electrode while flowing a large volume of gas, thereby spraying plasma in a jet state. The plasma sprayed from the plasma torch forms a plasma stream toward the base material. A raw material powder, when injected into the plasma stream, may be melted in a short time. Particularly, when the plasma spray apparatus generates a plasma jet in an open state to the atmosphere, it is called atmospheric plasma spraying. The present disclosure may be applied to atmospheric plasma spraying.

In the present disclosure, the powder injector 120 is configured to supply a raw material powder as a material for a sprayed coating. In the present disclosure, the raw material powder may include an yttrium aluminum oxide represented by Y—Al—O and a precursor thereof. In the present disclosure, the yttrium aluminum oxide may be YAG, YAM, or YAP. For example, the raw material powder may be YAG (Y₃Al₅O₁₂) or a YAG precursor.

In the present disclosure, a mixed powder of two or more powders capable of synthesizing YAG (Y₃Al₅O₁₂) within the plasma stream may be used as the YAG precursor. For example, the YAG precursor may be a mixed powder of Al₂O₃ and Y₂O₃. Additionally, the YAG precursor may include intermediate compounds that can be synthesized from Al₂O₃ and Y₂O₃. For example, the YAG precursor may include Y₂Al₈O₁₅ having a molar ratio of Al and Y of 1:4, YAlO₃ having a molar ratio of Al and Y of 1:1, Y₄Al₂O₉ having a molar ratio of Al and Y of 4:2, and Y₈Al₂O₁₈ having a molar ratio of Al and Y of 4:1, in addition to YAG (Y₃Al₅O₁₂), and may include compounds having other molar ratios in addition to the exemplified intermediate compounds. These intermediate compounds may be mixed with Al₂O₃ powder and used as mixed powders.

In the present disclosure, the raw material powder may be a powder that is molded in a granular form. For example, the raw material powder may be a molded body obtained by spray drying of a YAG powder. Alternatively, the raw material powder may be prepared by melting a part of the spray dried molded body through heat treatment or plasma treatment.

In the present disclosure, the raw material powder may include an additional powder composition in addition to YAG or a YAG precursor. In such a case, a composite coating containing an yttrium aluminate phase other than YAG can also be formed.

The apparatus of the present disclosure includes the coolant injector 130. The coolant injector 130 is configured to spray a coolant. In the present disclosure, the coolant is water, with deionized water being preferred.

In the present disclosure, the coolant injector 130 is preferably arranged at the rear end of the powder injector 120 on the path of the plasma stream.

In the present disclosure, the separation distance of the coolant injector 130 from the plasma nozzle is preferably 20-50 mm. A close separation distance may cause an interference with the powder injector, and a separation distance exceeding 50 mm may reduce droplet cooling and powder particle size filtering effects.

The distance between the powder injector 120 and the coolant injector 130 may be appropriately designed considering the degree of melting of the supplied powder, the degree of cooling by the coolant, or the like, and the apparatus 100 may include a control member for controlling the arrangement position of the coolant injector 130.

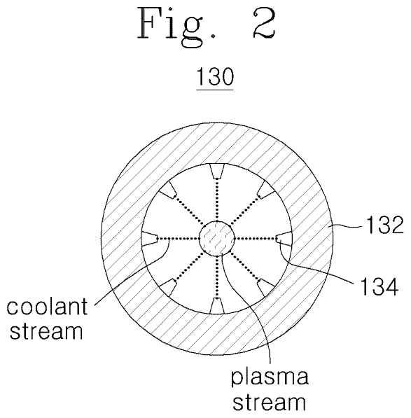

FIG. 2 is an exemplary plane diagram of the coolant injector in FIG. 1. FIG. 2 shows the coolant injector viewed from the axial direction of the plasma stream.

Referring to FIG. 2, the coolant injector 130 includes a coolant flow path 132 and a plurality of coolant spray orifices 134 attached to the coolant flow path. For example, the shape of the coolant flow path 132 is not particularly limited. For instance, as shown, the flow path may have a ring shape, and a plurality of spray orifices 134 may be arranged along the inner circumference of the ring-shaped coolant flow path. In the present disclosure, the number of spray orifices 134 may be appropriately set, and as shown, for example, eight orifices may be arranged at an equal angle toward the center of the coolant flow path.

In the present disclosure, the size of the orifices may be appropriately designed, but the size is preferably 0.007-0.011 in.

In the present disclosure, the flow rate of the coolant sprayed from the coolant injector 130 is preferably 100 ml/min to 500 ml/min. A flow rate of 500 ml/min or more suppresses the formation of splats due to the supply of excessive water, posing difficulty in normal film formation.

A coolant source (not shown) may be connected to the coolant flow path 132. In the present disclosure, the coolant temperature may be appropriately set, and, for example, room-temperature DI water may be used.

Preferably, the coolant stream from the coolant injector 130 intersects the plasma stream. FIGS. 1 and 2 illustrate an example where the coolant stream is substantially orthogonal to the plasma stream, but the intersection angle between the coolant stream and the plasma stream may be set variously. For example, the intersection angle of the coolant stream axis and the plasma stream axis may be appropriately adjusted in the range of 45-135°.

In the present disclosure, the coolant stream has a much lower temperature than the plasma stream and/or the powder within the plasma stream, and thus can cool the plasma stream and/or the powder within the stream. As such, the term “coolant” herein is given since the temperature of a liquid sprayed from the coolant injector 130 is relatively lower than the temperature of the plasma stream or the molten powder, and is not intended to define the YAG crystallization mechanism of the present disclosure. Highly crystalline YAG spray coatings obtained by the apparatus and method of the present disclosure may be due to the cooling effect of the coolant or due to a different mechanism therefrom. For example, the coolant in the present disclosure may reduce the internal energy of the molten droplets within the plasma stream. This reduction in the internal energy can mitigate the rapid cooling effect occurring after the molten droplets have collide with the base material. Therefore, the degree of crystallization of the coating 14 containing YAG that has collided with the base material can be increased.

In the present disclosure, a YAG-containing plasma sprayed coating 14 exhibits a high degree of crystallization. The sprayed coating of the present disclosure has a microstructure in which crystalline regions and amorphous regions alternately appear in the two-dimensional cross-section. In the present disclosure, the crystalline regions exhibit higher hardness than the amorphous regions. Preferably, the Vickers hardness (Hv) of the crystalline regions may be 1000 or more, 1050 or more, 1100 or more, or 1150 or more. These values are much higher than 600-790, which was the Vickers hardness (Hv) of the amorphous regions within the plasma sprayed coating. For example, in the present disclosure, the ratio of the Vickers hardness (B) of the crystalline regions to the Vickers hardness (A) of the amorphous regions may be 1.3 or more, 1.35 or more, 1.40 or more, 1.45 or more, 1.50 or more, 1.55 or more, 1.60 or more, 1.65 or more, 1.70 or more, 1.75 or more, or 1.80 or more.

Additionally, the plasma sprayed coating of the present disclosure has a high degree of crystallization. In the present disclosure, the degree of crystallization may be determined from the peaks and background intensities corresponding to the crystal planes of YAG (cubic) on the XRD pattern. For example, the degree of crystallization may be obtained by the HighScore Plus software mounted on the EMPYREAN equipment (X-ray source: Cu Ka, voltage: 40 kW, current: 30 mA) from Panalytical B.V.

The degree of crystallization calculated in the present disclosure may be 35% or more, 40% or more, 45% or more, 50% or more, 55% or more, 60% or more, 65% or more, 70% or more, 75% or more, or 80% or more.

The cross-section of the YAG sprayed coating of the present disclosure may be divided into bright regions and dark regions on the electron microscope image. The bright regions on the electron microscope image correspond to the crystalline regions. For example, the average area of the crystalline regions may be 100 μm² or more, 200 μm² or more, 300 μm² or more, or 400 μm² or more.

In the present disclosure, the plasma sprayed coating preferably has a high rate of crystallization and a low porosity. In the present disclosure, the porosity of the coating may be controlled by the particle size of the raw material powder. Preferably, in the present disclosure, the plasma sprayed coating may be 5% or less, 4.5% or less, 4% or less, 3.5% or less, 3.0% or less, 2.5% or less, 2.0% or less, 1.5% or less, 1.4% or less, 1.3% or less, or 1.2% or less.

Hereinafter, the present disclosure will be described with reference to exemplary embodiments of the present disclosure.

### A. Raw Material Powder for Spray Coating

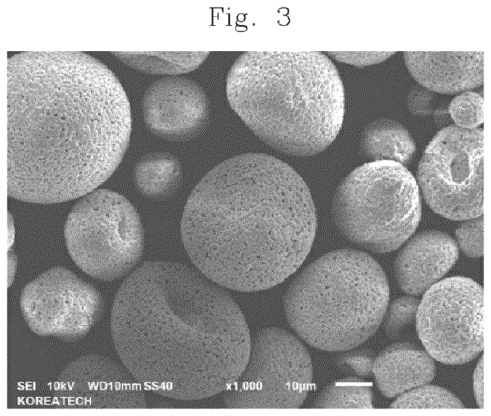

A YAG powder having a particle size of 1 μm or less was granulated to prepare a raw material powder for spray coating. The prepared granular powder had different D50 values ranging from 18 to 75 μm. FIG. 3 is a SEM image of a granular powder sample manufactured in the present disclosure.

### B. Manufacturing of Sprayed Coating

The raw material powder for spray coating and the apparatus in FIG. 1 were used to manufacture a sprayed coating by atmospheric plasma spraying (APS). Particularly, Al 6061 (50 mm*50 mm*5 mm) was used as a base substrate.

Plasma spraying conditions for manufacturing of a sprayed coating are shown in Table 1.

TABLE 1

| | | | | | | | | | | Separation |
|---|---|---|---|---|---|---|---|---|---|---|
| | | | | | | | | | | distance |
| | | | | Injection | | Injection | | Injection | Transfer | from base |
| Voltage | Current | Power | Gas | volume | Gas | volume | Gas | volume | pressure | material |
| (V) | (A) | (kW) | 1 | (SCFH) | 2 | (SCFH) | 3 | (SCFH) | (SCFH) | (mm) |
| 230-270 | 380-420 | 95-120 | Ar | 300-340 | H₂ | 120-160 | N₂ | 120-160 | 15-45 | 80-160 |

Experiments were conducted by varying the particle size (D50) of the raw material powder, the separation distance between the plasma torch nozzle and the base material, and the flow rate of the coolant injector. As a result of the experiments, when a granular powder was used, the flow rate of the coolant needed to be adjusted as the particle size of the powder increased. It was found preferable, for the formation of a favorable coating, to reduce the flow rate of the coolant as the particle size of the granular powder increased.

Meanwhile, for comparison, samples were manufactured by plasma spray coating of a granular raw powder without using a coolant injector (Comparative Examples 3 to 7), and samples were manufactured by plasma spray coating of a suspension of a non-granulated raw powder (D50=5.8 μm) with using a coolant injector (Comparative Examples 1 and 2). Like in Comparative Examples 1 and 2, a non-granulated fine powder of less than 15 μm was difficult to supply in a dry manner, and thus was supplied in the form of a suspension.

The experimental conditions of the respective examples and comparative examples are shown in Table 2. The porosity, hardness, and degree of crystallization of the manufactured sprayed coatings were measured. The measurement method of each property was as follows.
Porosity: After mounting a sample with a coating to be measured, the cross-section of the coating was polished with #400 to #4000 grit sandpaper and a diamond (3 to 0.05 μm) suspension. Thereafter, an image of the polished surface was taken using an electron microscope, and the porosity was determined by calculating the ratio of the area of inner pores to the total coating area using the ImagePro program.
Hardness: While the microstructure of the cross-section of a coating was observed using an optical microscope, the hardness of an amorphous part (A) and the hardness of a crystalline part (B) were measured. The hardness was measured using the HM-124 equipment from Mitutoyo, according to ASTM E384.
Degree of crystallization: The surface of a coating was analyzed by X-ray diffraction, and the degree of crystallization was determined from the peaks on the obtained XRD pattern. The degree of crystallization was determined by creating a baseline on the XRD graph and calculating the area of a peak part and the area of an amorphous part based on the baseline. The X-ray diffraction analysis and degree of crystallization were measured and determined by the EMPYREAN equipment from Panalytical B. V (X-ray source: Cu Ka, voltage: 40 kW, current: 30 mA).

The measurement results are shown in Table 2.

TABLE 2

| | | | | | | | | Powder |
|---|---|---|---|---|---|---|---|---|
| | | | | | | | | particle |
| | Separation | Coolant | | Amorphous | Crystalline | | | size |
| | distance | flow | Porosity | Hardness | Hardness | Hardness | Degree of | (D50, |
| Classification | (mm) | rate | (%) | A | B | ratio | crystallization | μm) |
| Example 1 | 100 | 320 | 1.54 | 785 | 1110 | 1.41 | 75% | 30 |
| | | ml/min | | | | | | |
| Example 2 | 100 | 400 | 1.82 | 721 | 1096 | 1.52 | 50% | 30 |
| | | ml/min | | | | | | |
| Example 3 | 100 | 240 | 1.04 | 755 | 1072 | 1.42 | 45% | 18 |
| | | ml/min | | | | | | |
| Example 4 | 100 | 240 | 3.06 | 785 | 1046 | 1.33 | 70% | 45 |
| | | ml/min | | | | | | |
| Example 5 | 100 | 240 | 3.41 | 601 | 1112 | 1.85 | 73% | 60 |
| | | ml/min | | | | | | |
| Example 6 | 100 | 160 | 4.16 | 604 | 1096 | 1.81 | 82% | 75 |
| | | ml/min | | | | | | |
| Comparative | 76 | 320 | 1.87 | 666 | — | — | 25% | 5.8 |
| Example 1 | | ml/min | | | | | | |
| Comparative | 100 | 320 | 2.16 | 643 | — | — | 34% | 5.8 |
| Example 2 | | ml/min | | | | | | |
| Comparative | 100 | — | 1.57 | 802 | — | — | 25% | 30 |
| Example 3 | | | | | | | | |
| Comparative | 100 | — | 1.88 | 786 | — | — | 27% | 18 |
| Example 4 | | | | | | | | |
| Comparative | 100 | — | 2.54 | 702 | 1006 | 1.43 | 55% | 45 |
| Example 5 | | | | | | | | |
| Comparative | 100 | — | 2.55 | 654 | 1021 | 1.56 | 58% | 60 |
| Example 6 | | | | | | | | |
| Comparative | 100 | — | 2.68 | 677 | 1156 | 1.71 | 68% | 75 |
| Example 7 | | | | | | | | |

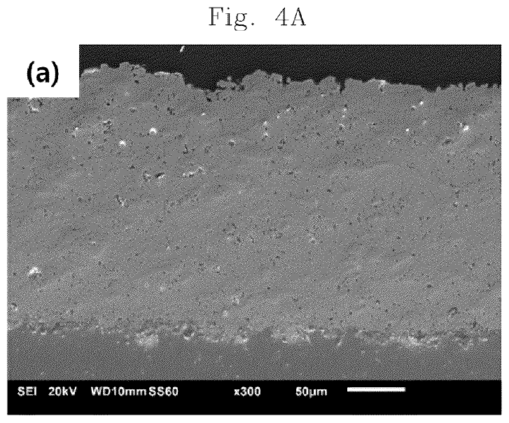

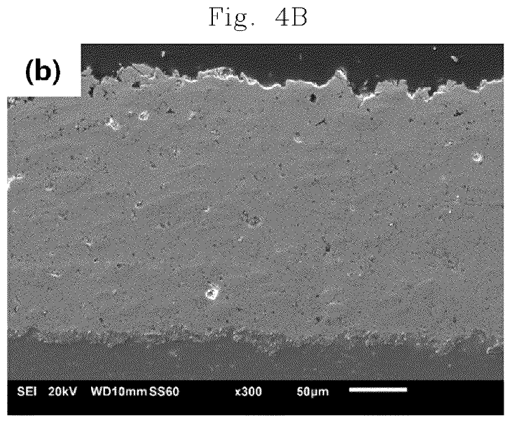

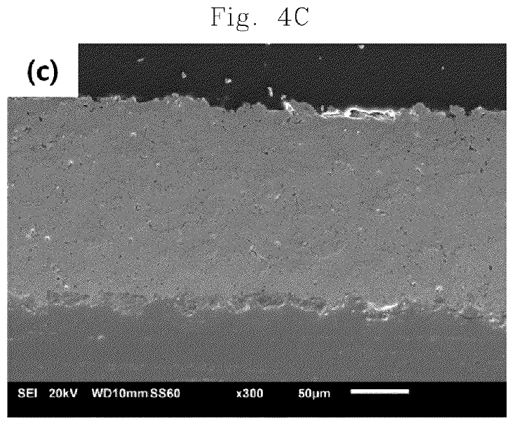

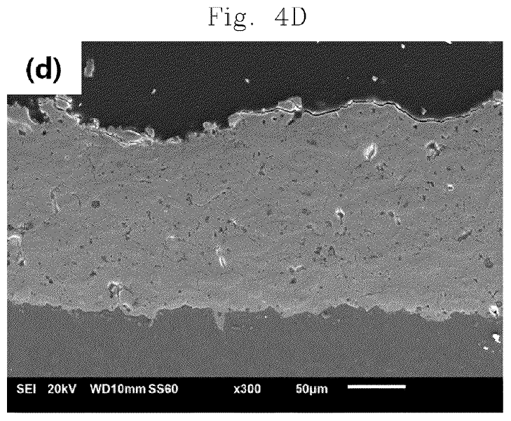

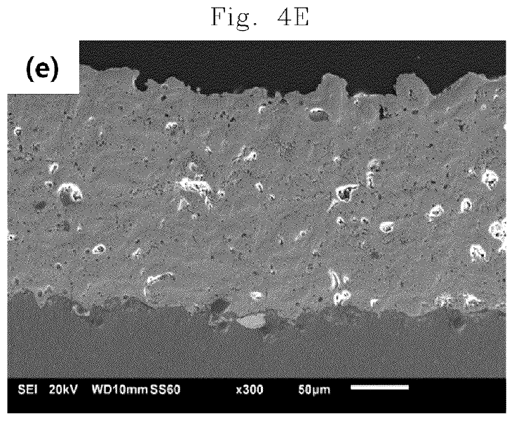

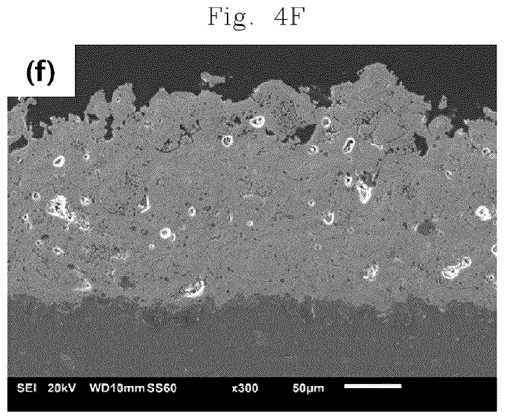

FIGS. 4A to 4F are electron microscopic images taken after the cross-sections of the specimens of Examples 1 to 6 were polished, respectively.

Referring to FIG. 4A, a dense sprayed coating was formed on the surface of a base material. In such a situation, a slight increase in coolant flow rate resulted in a slight increase in pores, as shown in FIG. 4B.

Meanwhile, as can be seen from FIG. 4C, a reduction in particle size of the raw material powder resulted in the formation of a denser coating. However, as can be seen from FIGS. 4D to 4F, the pores tended to increase as the particle size increased.

In the present disclosure, the particle size (D50) of granules, which are a raw material powder, is preferably 10 μm or larger, 15 μm or larger, or 18 μm or larger. In the present disclosure, the particle size (D50) of granules is preferably 70 μm or smaller, 60 μm or smaller, 50 μm or smaller, or 45 μm or smaller.

Examples 4 to 6 showed a very high degree of crystallization, which indicates that particles are deposited in an incompletely molten state during spray coating, remaining in a powder form inside the coating layer. Comparative Examples 5 and 7 also showed a relatively high degree of crystallization, which seems to be due to the same reason.

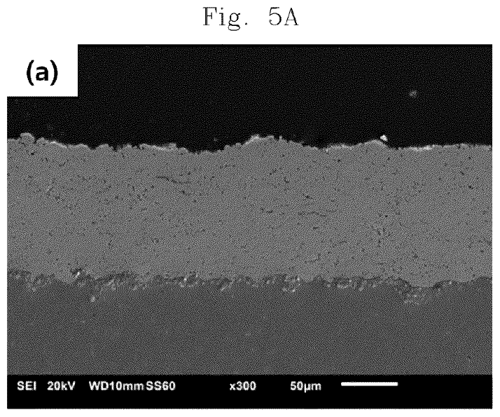

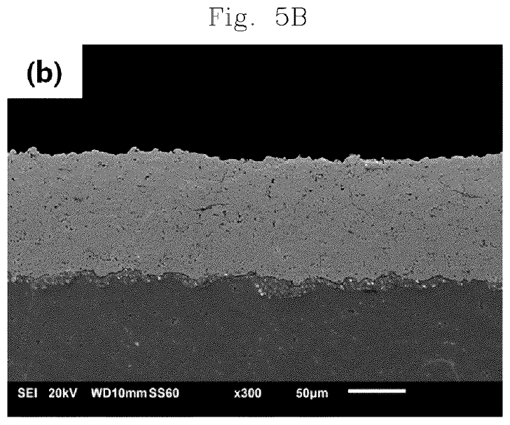

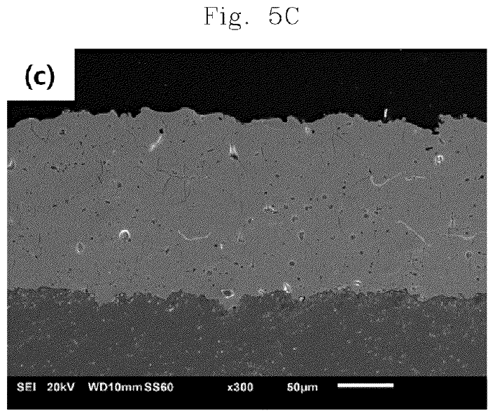

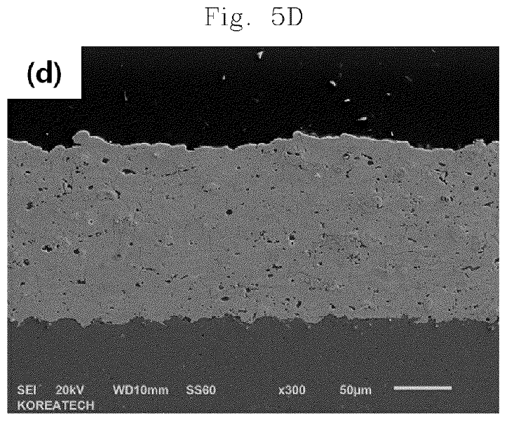

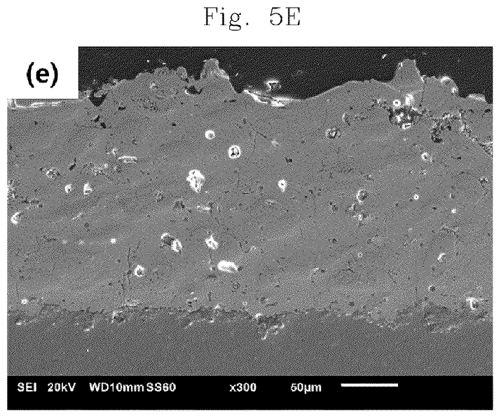

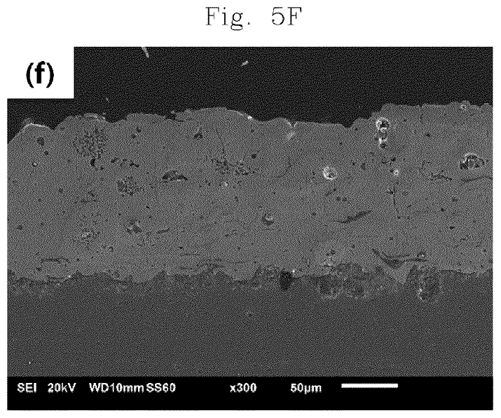

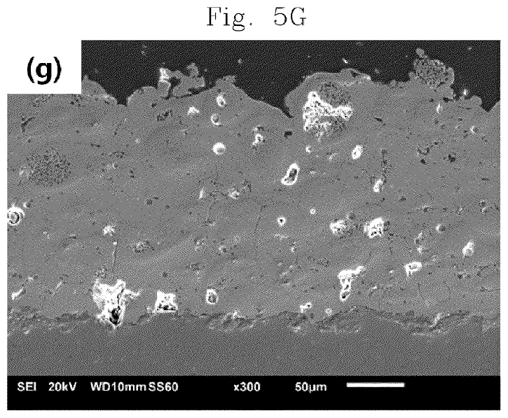

FIGS. 5A to 5G are electron microscopic images taken after the cross-sections of the specimens Comparative Example 1 to 7 were polished, respectively.

Referring to FIGS. 5A and 5B, dense coatings were obtained from specimens manufactured using a suspension of a fine raw material powder that had not been granulated. However, samples with a small particle size manufactured from a suspension showed a very low degree of crystallization.

Meanwhile, specimens manufactured by plasma spray coating of a granular raw material powder without using a coolant injector obtained dense coatings, but showed a low degree of crystallization compared with specimens of the corresponding examples.

Referring to FIGS. 5C to 5G, the degree of densification of a coating according to the increase or decrease in the particle size of the raw material powder showed a similar trend to the examples even when a coolant injector was not used.

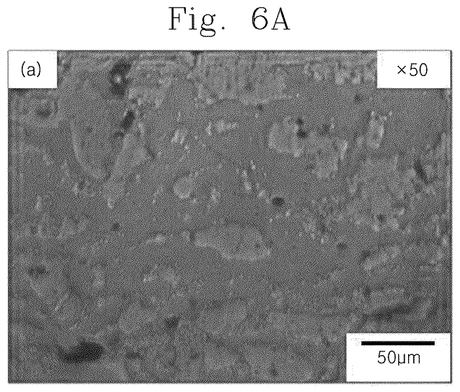

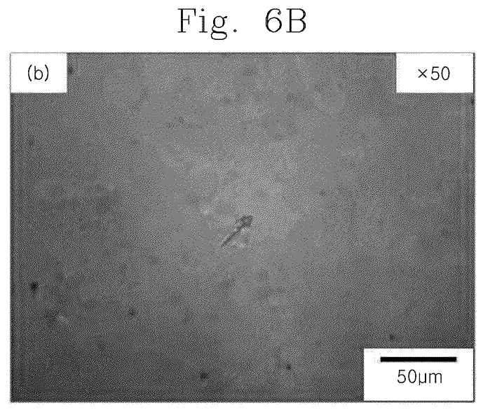

FIGS. 6A and 6B are optical microscopic images obtained by observing a cross-section and a surface of the coating of Example 1, respectively.

Referring to FIG. 6A, each bright region and each dark region are shown on the image, indicating that these regions had different phases. As can be seen from the XRD pattern to be described later, the former corresponds to a crystalline phase, and the latter corresponds to an amorphous phase. FIG. 6B also confirms the crystalline phase (see the arrow).

The hardness value of the crystalline phase presented in the example of the present disclosure is the hardness value measured in the arrow region, and the hardness value of the amorphous phase is the hardness value measured in the dark region.

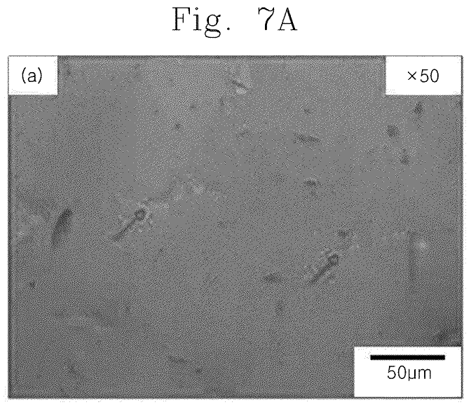

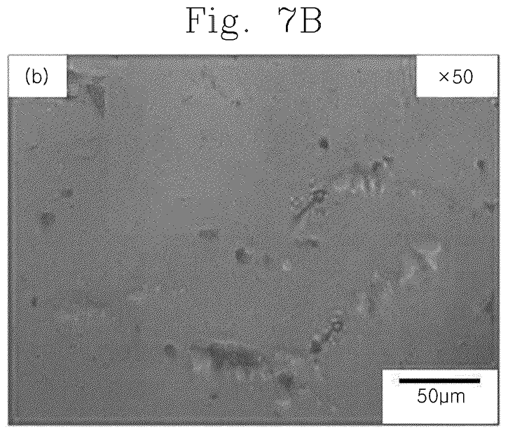

FIGS. 7A and 7B are optical microscopic images obtained by observing a cross-section and a surface of the coating of Comparative Example 3, respectively.

Referring to FIG. 7, bright regions (see the arrows) were also observed in Comparative Example 3, but the area thereof was significantly smaller than that in Example 1. Since the area of the crystalline phase regions was much smaller than the size of the indenter for measuring the Vickers hardness as stated above, the Vickers hardness measured for the crystalline phase regions was substantially the same as the value measured in the amorphous phase regions, and therefore, the Vickers hardness for the crystalline phase regions is not shown in Table 2.

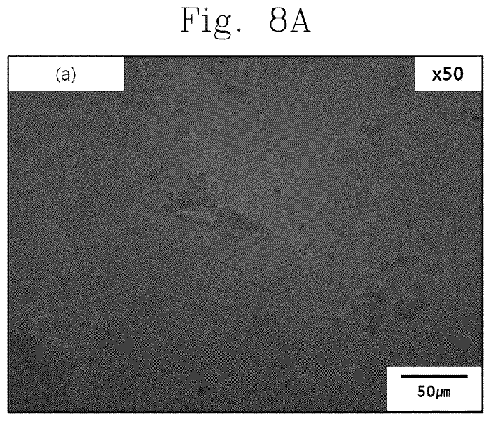

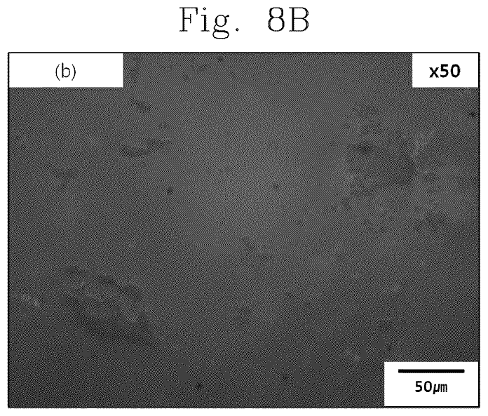

FIGS. 8A and 8B are optical microscopic images obtained by observing the surfaces of the coatings of Comparative Examples 1 and 2, respectively. Like in Comparative Example 3, the area of the crystalline phase regions was much smaller than the size of the indenter for measuring the Vickers hardness, the Vickers hardness measured for the crystalline phase regions was substantially the same as the value measured in the amorphous phase regions, and therefore, the Vickers hardness for the crystalline phase regions is not shown in Table 2.

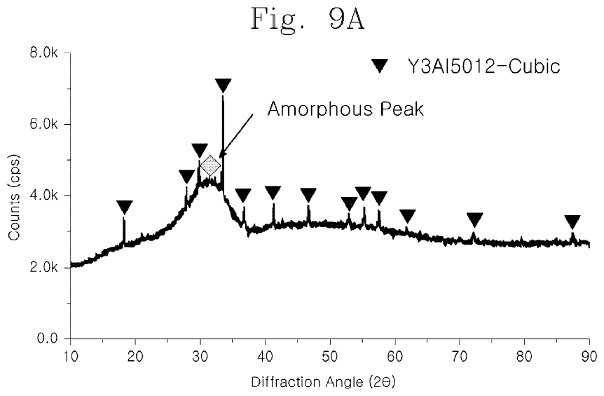

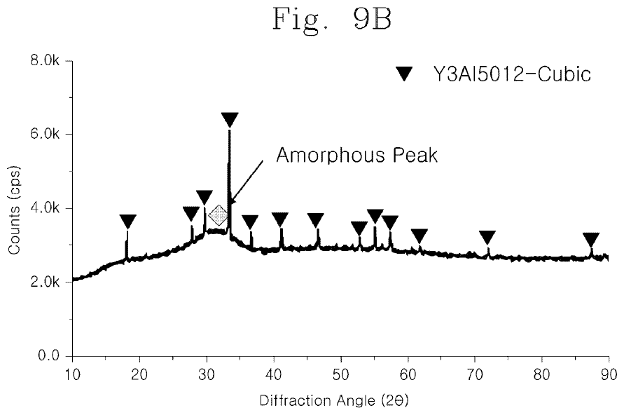

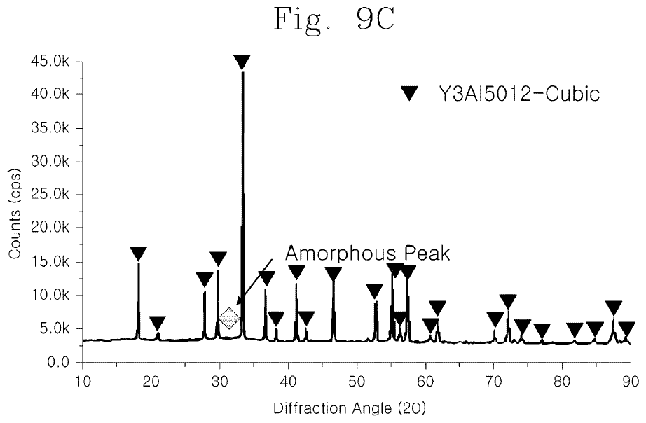

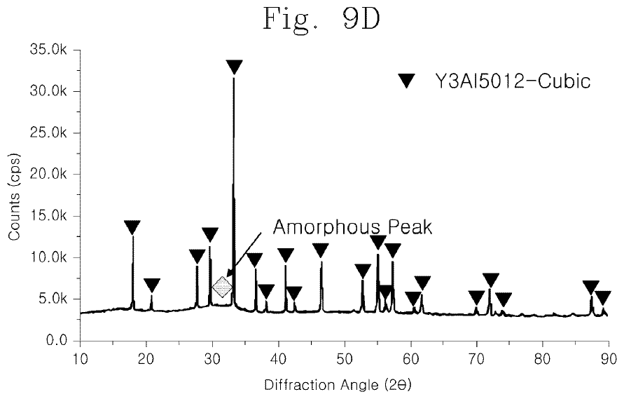

FIGS. 9A to 9D show XRD analysis results of plasma sprayed coatings formed in Comparative Examples 1 and 2 and Examples 1 and 2, respectively.

As shown in FIGS. 9A and 9B, the background intensity was very high at a low angle around 20=30°, and the background intensity was observed up to around 20=60°.

Meanwhile, as shown in FIGS. 9C and 9D, the background intensity at a low angle was significantly attenuated when the coolant injection was used in the plasma spray coating process.

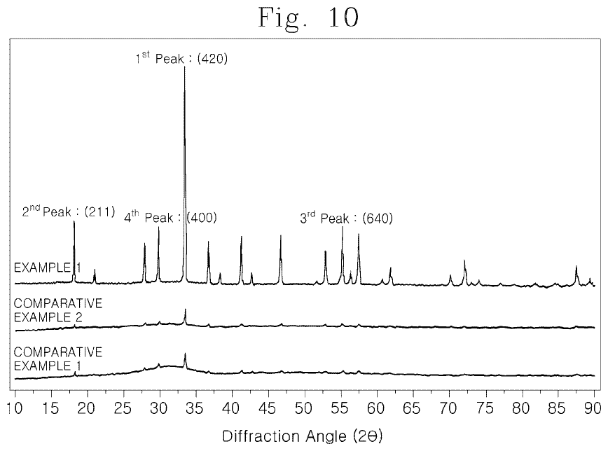

FIG. 10 is a graph showing the results of indexing XRD peaks for some patterns in FIG. 9.

As shown, in the coating showing a high degree of crystallization as in Example 1, the diffraction intensities of the peaks for crystal planes (420), (211), (640), and (400) were highest in that order, confirming that a YAG coating was formed. In this exemplary embodiment, four crystal planes corresponded to 2θ=18.09°, 2θ=29.75°, 2θ=33.35°, and 2θ=55.13° (2θ error range: ±1°). The degree of crystallization was calculated from the XRD analysis results, and the results are shown in Table 2.

The present disclosure has been described above with exemplary embodiments and drawings, but these are only provided to help a more general understanding of the present disclosure, and the present disclosure is not limited to the exemplary embodiments. A person skilled in the art to which the present disclosure pertains will recognize that various modifications and variations can be made without departing from the essential characteristics of the present disclosure. The spirit of the present disclosure is defined by the appended claims rather than by the described exemplary embodiments above, and all changes and modifications that fall within metes and bounds of the claims, or equivalents of such metes and bounds are therefore intended to be embraced by the range of the spirit of the present disclosure.

What is claimed is:

1. A method for manufacturing a plasma sprayed coating containing YAG, the method comprising:
providing a granular powder containing crystalline YAG;
forming a plasma stream toward a base material from a plasma spray torch;
forming molten droplets of the granular powder by supplying the granular powder to the plasma stream;
providing a coolant stream in a direction intersecting the plasma stream containing the molten droplets; and
providing the base material with the plasma stream that has undergone the coolant stream, thereby forming a sprayed coating containing a crystalline phase and an amorphous phase.

2. The method of claim 1, wherein in the forming of molten droplets, the granular powder is partially melted in a state where the crystalline YAG is contained inside the molten droplets.

3. The method of claim 1, wherein the granular powder has a D50 of 15-75 μm.

4. The method of claim 1, wherein the granular powder has a D50 of 15-45 μm.

5. The method of claim 3, wherein the degree of crystallization of the sprayed coating is 45% or more.

6. The method of claim 3, wherein the porosity of the sprayed coating is 1-3.1%.

7. The method of claim 1, wherein the coolant stream includes water.

8. The method of claim 1, wherein the separation distance between the plasma torch and the base material is 80-160 mm.

9. The method of claim 1, wherein a coolant injector for supplying the coolant stream is included, and the coolant injector has a ring shape surrounding the plasma stream.

10. The method of claim 9, wherein a plurality of spray orifices toward the plasma steam are provided at the inner circumference of the coolant injector.

11. The method of claim 1, wherein the coolant stream has a flow rate of 100-500 ml/min.

12. The method of claim 1, wherein the Vickers hardness of the amorphous phase is 720-800.

13. The method of claim 1, wherein the Vickers hardness of the crystalline phase is 1000-1110.

14. The method of claim 1, wherein the ratio of the Vickers hardness of the crystalline phase to the Vickers hardness of the amorphous phase is 1.3-1.6.

15. A plasma sprayed coating containing Y—Al—O, wherein Y—Al—O in the sprayed coating includes a crystalline phase and an amorphous phase,
the crystalline phase contains YAG, and
the Vickers hardness (Hv) of the crystalline phase is 1000 or more.

16. The plasma sprayed coating of claim 15, wherein the ratio of the Vickers hardness of the crystalline phase to the Vickers hardness of the amorphous phase is 1.3 or more.

17. The plasma sprayed coating of claim 15, wherein the degree of crystallization of the YAG, calculated from the XRD pattern of the YAG, is 45% or more.

18. The plasma sprayed coating of claim 15, wherein the cross-section of the sprayed coating includes bright regions showing the crystalline phase on an optical microscopic image, and
the average area of the regions is 100 μm² or more.

19. A plasma-resistant member comprising:
a base material; and
the sprayed coating of claim 15 formed on the base material.

20. The method of claim 4, wherein
the degree of crystallization of the sprayed coating is 45% or more, and
the porosity of the sprayed coating is 1-3.1%.
